(19) United States
(12) Patent Application Publication
(10) Pub. No.: US 2023/0317542 A1
(43) Pub. Date: Oct. 5, 2023

(54) SEMICONDUCTOR DEVICE COMPRISING CONTACT PAD STRUCTURE

(71) Applicant: Infineon Technologies AG, Neubiberg (DE)

(72) Inventors: Jochen HILSENBECK, Villach (AT); Thomas SÖLLRADL, Arnoldstein (AT); Roman ROTH, Sattendorf (AT); Richard GAISBERGER, Velden (AT); Sophia OLES, Villach (AT); Helmut Heinrich SCHOENHERR, Villach (AT); Juergen STEINBRENNER, Notsch im Gailtal (AT)

(21) Appl. No.: 18/128,506

(22) Filed: Mar. 30, 2023

(30) Foreign Application Priority Data
Mar. 30, 2022 (DE) 102022107599.0

(51) Int. Cl. H01L 23/31; H01L 23/00; H01L 21/56

(52) U.S. Cl. CPC H01L 23/3192; H01L 23/3171; H01L 24/05; H01L 21/56; H01L 2224/05567; H01L 23/291

(57) ABSTRACT

A semiconductor device is proposed. The semiconductor device includes a contact pad structure over a first surface of a semiconductor body. The semiconductor device further includes a dielectric structure lining a sidewall and a boundary area on a top surface of the contact pad structure, wherein the dielectric structure includes a dielectric spacer at the sidewall of the contact pad structure.

### RELATED APPLICATION

This application claims priority to German Patent Application No. 102022107599.0, filed on Mar. 30, 2022, entitled “SEMICONDUCTOR DEVICE COMPRISING CONTACT PAD STRUCTURE”, which is incorporated by reference herein in its entirety.

### TECHNICAL FIELD

The present disclosure is related to a semiconductor device, in particular to a semiconductor device comprising a contact pad structure.

### BACKGROUND

In semiconductor devices, a wiring area over an active chip area typically includes one or more wiring levels including metal lines for enabling electric interconnection of transistors or other components in the chip or for enabling electric contact to components outside of the chip, such as, for example, via a contact pad structure. The metal lines in the wiring levels of a wiring area are typically required to meet many, partially conflicting, requirements for meeting demands on chip reliability. These requirements may include, inter alia, suitability for preventing penetration of humidity and subsequent corrosion that may lead to device failure, very good conductivity, chemical stability, electromigration resistance, low diffusivity in substrate material, for example.

Thus, there is a need for providing a semiconductor device with improved reliability.

### SUMMARY

An example of the present disclosure relates to a semiconductor device. The semiconductor device may include a contact pad structure over a first surface of a semiconductor body. The semiconductor device may further include a dielectric structure lining a sidewall and/or a boundary area on a top surface of the contact pad structure. The dielectric structure may include a dielectric spacer at the sidewall of the contact pad structure.

Another example of the present disclosure relates to a method of producing a semiconductor device. The method may include forming a contact pad structure over a first surface of a semiconductor body. The method may further include forming a dielectric structure lining a sidewall and/or a boundary area on a top surface of the contact pad structure. The dielectric structure may include a dielectric spacer at the sidewall of the contact pad structure.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of semiconductor devices and together with the description serve to explain principles of the examples. Further examples are described in the following detailed description and the claims.

FIGS. 1 and 2 illustrate partial cross-sectional views for illustrating examples of semiconductor devices including a contact pad structure and a dielectric spacer at a sidewall of the contact pad structure.

FIG. 3 illustrates an experimental image for illustrating an exemplary shape of a sidewall portion of the contact pad structure of a semiconductor device.

FIG. 4 illustrates a partial cross-sectional view for illustrating another example of a semiconductor device including dielectric spacers at sidewalls of a gate runner line and a source or emitter runner line.

FIGS. 5A to 5D and FIGS. 6A to 6C illustrate schematic cross-sectional views for illustrating process features of producing a semiconductor device.

### DETAILED DESCRIPTION

In the following detailed description, reference is made to the accompanying drawings, which form a part hereof and in which are shown by way of illustrations specific examples of semiconductor devices. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

Ranges given for physical dimensions include the boundary values. For example, a range for a parameter y from a to b reads as a y b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of a semiconductor device may include a contact pad structure over a first surface of a semiconductor body. The semiconductor device may further include a dielectric structure lining a sidewall and/or a boundary area on a top surface of the contact pad structure. The dielectric structure may include a dielectric spacer at the sidewall of the contact pad structure.

The semiconductor device may be or may include an integrated circuit, a discrete semiconductor device and/or a semiconductor module, for example. The semiconductor device may be or may include a power semiconductor device, such as, for example, a vertical power semiconductor device having a load current flow between the first surface and a second surface. The semiconductor device may be used in automotive, industrial power control, power management, sensing solutions and/or security in Internet of Things applications. The semiconductor device may be or may include a power semiconductor diode, a power semiconductor IGBT (insulated gate bipolar transistor), a reverse conducting (RC) IGBT, and/or a power semiconductor transistor, such as a power semiconductor IGFET (insulated gate field effect transistor, such as, for example, a metal oxide semiconductor field effect transistor), a JFET (junction field effect transistor), a HEMT (high-electron-mobility transistor), and/or a HFET (heterojunction field effect transistor). The power semiconductor device may be configured to conduct currents of more than 1 A or more than 10 A or even more than 30 A. For realizing a desired maximum load current, the semiconductor device may be designed by a plurality of parallel-connected cells. The parallel-connected cells may, for example, be transistor and/or diode cells formed in the shape of a strip and/or a strip segment. Of course, the device cells can also have any other shape, such as, for example, a circular shape, an elliptical shape, and/or a polygonal shape, such as an octahedral. The semiconductor device may be further configured to block voltages between load terminals, such as, for example, between emitter and collector of an IGBT, between cathode and anode of a diode, and/or between drain and source of a MOSFET, in the range of several tens, or several hundreds of up to several thousands of volts, such as, for example, 30V, 40V, 60V, 80V, 100V, 400 V, 650V, 1.2 kV, 1.7 kV, 3.3 kV, 4.5 kV, 5.5 kV, 6 kV, and/or 6.5 kV. The blocking voltage may correspond to a voltage class specified in a datasheet of the power semiconductor device, for example. The semiconductor device may also be or may also include a lateral semiconductor device, such as, for example, a lateral power semiconductor device, having a load current flow along a lateral direction, such as, for example, parallel to the first surface

For example, the semiconductor device may be implemented monolithically using a mixed technology. Such mixed technologies can be used, for example, to form analog circuit blocks in a chip by the bipolar devices included in this technology for providing interfaces to digital systems, and to form digital circuit blocks by the complementary metal-oxide-semiconductor (CMOS) devices included in this technology for providing signal processing, and to form low-, medium- or high-voltage or power blocks by field effect transistors included in this technology. Such mixed technologies are known, for example, as bipolar CMOS-DMOS, BCD technologies or smart power technologies, SPT, and are used in a variety of application areas and/or one or more fields such as, for example, lighting, motor control, automotive electronics, power management for mobile devices, audio amplifiers, power supply, hard disks, and/or printers.

The semiconductor device may be part of a BCD and/or Smart Power chip in one of the above application areas and/or one or more fields, for example.

The semiconductor body may be based on various semiconductor materials, such as, for example, silicon (Si), silicon-on-insulator (SOI), silicon-sapphire (SOS), silicon-germanium, germanium, gallium arsenide, silicon carbide, gallium nitride, and/or other compound semiconductor materials. The semiconductor body may be a semiconductor substrate, such as, for example, a semiconductor wafer, and may include one or more epitaxial layers deposited thereon, and/or may be back-thinned.

The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, interconnects may be arranged on the contact pad structure for electrically connecting circuit elements in the semiconductor body to elements, such as, for example, other semiconductor devices, outside of the semiconductor device.

The contact pad structure may be part of a wiring area over the semiconductor body. The wiring area may include one or more than one, such as, for example, two, three, four or even more wiring levels. Each wiring level may be formed by a single conductive layer or a stack of conductive layers, such as, for example, metal layer(s). The wiring levels may be lithographically patterned, for example. Between stacked wiring levels, an interlayer dielectric structure may be arranged. One or more contact plug(s) and/or one or more contact line(s) may be formed in openings in the interlayer dielectric structure to electrically connect parts, such as, for example, metal lines and/or contact areas, of different wiring levels to one another. The contact pad structure may be formed by one or more elements of the wiring area. For example, the contact pad structure may include parts of an outermost wiring level of the wiring area, such as, for example, the wiring level having a largest vertical distance to the first surface of the semiconductor body. For example, the contact pad structure may directly adjoin the first surface of the semiconductor body. The boundary area of the contact pad structure may be a peripheral part of the top surface of the contact pad structure. The boundary area of the contact pad structure may partly or fully surround a central part of the contact pad structure. The central part of the contact pad structure may be a central part on the top surface of the contact pad structure where, for example, an interconnect directly adjoins to the contact pad structure.

The dielectric spacer at the sidewall of the contact pad structure may differ from one or more other parts of the dielectric structure in material composition, for example. For example, parts of the dielectric structure may be formed by separate layer deposition processes. The dielectric spacer may also be merged with other dielectric parts of same material composition, such as, for example, in case that a back-etch of a dielectric layer for forming the dielectric spacer does not fully, but only partly, remove the dielectric layer in one or more regions next to the dielectric spacer. The dielectric structure may include a plurality of dielectric parts, such as, for example, stacked layers, or spacers, that may differ from one another with respect to material composition, dimensions (e.g., thickness), function (e.g., electric isolation, diffusion barrier, and/or adhesion properties). The dielectric structure may include a variety of dielectric materials including, inter alia, oxides (e.g., silicate glass, deposited SiO₂, and/or thermal SiO₂), nitrides (e.g., Si₃N₄), high-k dielectrics, low-k dielectrics, or any combination thereof. For example, the dielectric spacer may be formed as a silicate glass dielectric spacer.

By providing the dielectric spacer at the sidewall of the contact pad structure, generation of weak points in the dielectric structure may be counter-acted. For example, generation of growth gaps and/or seamlines originating from bottom edges of the contact pad structure may be avoided or reduced. This may allow for an improvement of the reliability of the semiconductor device.

For example, the semiconductor device may further comprise an interconnect on the top surface of the contact pad structure. The interconnect may directly adjoin to the top surface of the contact pad structure, for example. The interconnect may be based on, inter alia, clip bonding, nailhead or ball bonding, wedge bonding, soldering, sintering, ribbon bonding, or a combination thereof, for example.

For example, a part of the sidewall of the contact pad structure may have a convex shape. The convex shape may be caused by process technology, for example. The convex shape at the sidewall of the contact pad structure may be present with respect to a part of the contact pad structure having a same material composition. The convex shape at the sidewall of the contact pad structure may result, in a first part of the contact pad structure, to a positive slope of the sidewall relative to a perpendicular to the first surface, and/or, in a second part of the contact pad structure (e.g. between the first part and the first surface), to a negative slope of the sidewall relative to the perpendicular to the first surface. Since a variety of processes may be applied for forming the contact pad structure, other shapes of the sidewall may also be present, such as, for example, tapered or vertical sidewalls.

For example, the contact pad structure may be a source contact pad structure, an emitter contact pad structure, and/or a gate contact pad structure.

For example, the dielectric spacer may be arranged between a first liner dielectric of the dielectric structure and a second liner dielectric of the dielectric structure. The dielectric spacer may be sandwiched between the first liner dielectric of the dielectric structure and the second liner dielectric of the dielectric structure. In other words, in a cross-sectional view, the first liner dielectric and the second liner dielectric may encapsulate and/or fully surround the dielectric spacer. The first liner dielectric may directly adjoin to the sidewall of the contact pad structure. For example, the first liner dielectric may also directly adjoin to the dielectric spacer on the opposite side, such as, for example, opposite to where the first liner dielectric directly adjoins to the sidewall of the contact pad structure, for example. The second liner dielectric may directly adjoin to the dielectric spacer, such as, for example, opposite to where the first liner dielectric directly adjoins to the dielectric spacer. The second liner dielectric may also directly adjoin to the first liner dielectric, such as, for example, in a region that laterally confines the spacer dielectric. For a contact pad structure including Cu, the dielectric structure may include, in addition to the dielectric spacer, the first liner dielectric and/or the second liner dielectric. In other examples, the first liner dielectric is optional and may also be omitted, such as, for example, when forming the contact pad structure by Al based materials.

For example, the first liner dielectric may include a dielectric layer and/or a dielectric layer stack, such as, for example, a nitride liner (e.g. SiN), or an oxide liner (e.g. Al₂O₃, and/or deposited or thermal SiO₂), or a combination thereof. For example, the first liner dielectric may include a stack of an Al₂O₃ layer and a SiN layer. For example, the second liner dielectric may include a dielectric layer and/or a dielectric layer stack, such as, for example, a nitride liner (e.g. SiN), or an oxide liner (e.g. silicate glass, and/or deposited SiO₂), or a combination thereof. For example, the second liner dielectric may include a SiN liner and/or a silicate glass. The silicate glass may be arranged between the first liner dielectric and the SiN liner of the second liner dielectric, for example.

For example, the semiconductor device may further comprise a polyimide resin on the second liner dielectric. The polyimide resin may serve as a chip passivation that directly adjoins to the second liner dielectric, for example. For example, a part of the polyimide resin may also adjoin to the first liner dielectric or part thereof.

For example, the semiconductor device may further comprise at least one of a gate runner line and/or a gate finger line electrically connecting gate electrodes of transistor cells to a gate contact pad structure. The gate runner line may partly or fully surround a transistor cell array, for example. The gate runner line may be arranged between an edge of the semiconductor body, such as, for example, die, and the contact pad structure. The dielectric structure may extend between the contact pad structure and the gate runner line and/or may line a sidewall and a top surface of the gate runner line. For example, the dielectric structure may include a second dielectric spacer at the sidewall of the gate runner line. The dielectric spacer at the sidewall of the contact pad structure and/or the second dielectric spacer may be concurrently formed, for example. In other words, a single spacer process may be used to form the dielectric spacer and/or the second dielectric spacer. Apart from the dielectric spacer and the second dielectric spacer, one or more additional dielectric spacers may be concurrently formed. The one or more additional dielectric spacer may include, for example, one or more spacers at opposite sidewalls of the contact pad structure and the gate runner line, respectively.

For example, the semiconductor device may further comprise a source and/or emitter runner line electrically connecting source and/or emitter regions of transistor cells to the contact pad structure. The source and/or emitter runner line may be arranged between an edge of the semiconductor body and the contact pad structure, or partially between the edge of the semiconductor body and a gate runner line. The dielectric structure may extend between the contact pad structure and the source or emitter runner line and/or may line a sidewall and a top surface of the source or emitter runner line. The source or emitter runner line may partly or fully surround a transistor cell array, for example. The dielectric structure may include, in addition the first and optional second dielectric spacer, a third dielectric spacer at the sidewall of the source and/or emitter runner line. The dielectric spacer, the second dielectric spacer, and/or the third dielectric spacer may be concurrently formed, for example.

For example, the contact pad structure may include at least one of Cu, Au, AlCu, Ag, or alloys thereof. The at least one of Cu, Au, AlCu, Ag, or alloys thereof that is included in the contact pad structure may be selected and/or adjusted with respect to electric conductivity, for example. The contact pad structure may include further structural elements, such as, for example, sub-layers, serving for a different purpose. For example, the contact pad structure may include at least one of one or more diffusion barrier layer(s), and/or one or more adhesion layer(s). For example, the one or more diffusion barrier layer(s) may have a smaller thickness than the layer or layer stack including the at least one of Cu, Au, AlCu, Ag, or alloys thereof. Likewise, the one or more adhesion barrier layer(s) may have a smaller thickness than the layer or layer stack including the at least one of Cu, Au, AlCu, Ag, or alloys thereof. The one or more diffusion barrier layer(s) may be arranged between the first surface and the layer or layer stack including the at least one of Cu, Au, AlCu, Ag, or alloys thereof. Likewise, the one or more adhesion barrier layer(s) may be arranged between the first surface and the layer or layer stack including the at least one of Cu, Au, AlCu, Ag, or alloys thereof. The contact pad structure may have a pad finishing for surface protection or special joining techniques like soft solder and/or sintering. For example, typical materials may include NiP, NiMoP, Pd, Ag, Au as single layer or layer stacks such as NiP/Pd/Au.

For example, a vertical distance between the first surface and a top surface of the contact pad structure may be in a range from 2 μm to 50 μm.

For example, a width of the spacer dielectric at a bottom side of the spacer dielectric may be larger than a thickness of the first liner dielectric on the top surface of the contact pad structure.

For example, a width of the spacer dielectric at a bottom side of the spacer dielectric may be smaller than a thickness of the second liner dielectric on the top surface of the contact pad structure. In some other examples, the width of the spacer dielectric at a bottom side of the spacer dielectric may also be larger than a thickness of the second liner dielectric on the top surface of the contact pad structure.

Functional and structural details, such as, for example, material(s), dimension(s), and/or purpose, described with respect to the examples of a semiconductor device above shall likewise apply to the examples of producing the semiconductor device described further below.

An example of a method of producing a semiconductor device may comprise forming a contact pad structure over a first surface of a semiconductor body. The method may further comprise forming a dielectric structure lining a sidewall and/or a boundary area on a top surface of the contact pad structure. The dielectric structure may include a spacer dielectric at the sidewall of the contact pad structure.

For example, forming the dielectric structure may include forming a first liner dielectric of the dielectric structure on the sidewall and/or on the top surface of the contact pad structure. The method may further include forming the dielectric spacer by a spacer etch process. The method may further include forming a second liner dielectric on the dielectric spacer and/or on the first liner dielectric. The spacer etch process may be carried out by an anisotropic etch process, such as, for example, by an anisotropic dry etch process, such as a reactive ion etch process.

For example, forming the dielectric spacer by a spacer etch process may include forming a dielectric processing layer over the first surface of the semiconductor body. The dielectric layer may be partly etched back so that a first part of the dielectric processing layer remains as the spacer dielectric and/or a second part of the dielectric processing layer remains over the first surface of the semiconductor body. Thus, the first part and/or the dielectric spacer may have a same material composition and/or may be merged.

The examples and features described above and below may be combined.

Functional and structural details (e.g. materials, dimensions) described with respect to the examples above shall likewise apply to the examples illustrated in the figures and described further below.

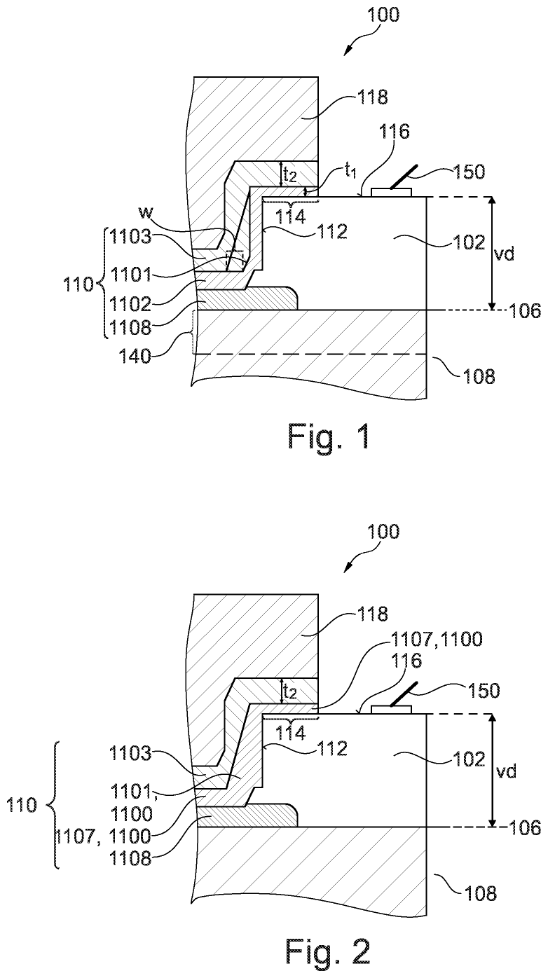

FIG. 1 schematically and exemplarily shows a semiconductor device 100. The semiconductor device 100 incudes a contact pad structure 102 over a first surface 106 of a semiconductor body 108. The semiconductor device 100 further includes a dielectric structure 110 lining a sidewall 112 and a boundary area 114 on a top surface 116 of the contact pad structure 102. The dielectric structure 110 includes a dielectric spacer 1101 at the sidewall 112 of the contact pad structure 102. The dielectric spacer 1101 is arranged between a first liner dielectric 1102 of the dielectric structure 110 and a second liner dielectric 1103 of the dielectric structure 110. The first liner dielectric 1102 directly adjoins to the sidewall 112 of the contact pad structure 102, and the second liner dielectric 1103 directly adjoins to the dielectric spacer 1101. In the cross-sectional view of FIG. 1, the first liner dielectric 1102 and the second liner dielectric 1103 encapsulate or fully surround the dielectric spacer 1101. The dielectric structure 110 further includes a dielectric part 1108 that directly adjoins to the first surface 106 of the semiconductor body 108. For example, the dielectric part 1108 may include a gate dielectric (e.g., gate oxide layer), or a field dielectric (e.g., field dielectric oxide), or an intermediate dielectric (e.g., intermediate oxide layer), or any combination thereof. The semiconductor device 100 further includes a polyimide resin 118 on the second liner dielectric 1103.

The semiconductor device may further include an interconnect 150 on the top surface 116 of the contact pad structure 102. Depending on the type of semiconductor device (e.g., integrated circuit, discrete semiconductor device, IGBT, FET, diode, and/or thyristor), and depending on the type of contact pad structure (e.g., source contact pad structure, emitter contact pad structure, anode contact pad structure, gate runner liner, source runner line, and/or anode runner line), a device-specific arrangement of doped semiconductor regions (e.g. n-doped source region and p-doped body region for an n-channel FET, n-doped emitter region and p-doped body region for an n-channel IGBT, and/or p-doped anode region for a diode) and optional non-semiconductor regions (e.g. trench electrode structures) are arranged in the semiconductor body 108 (illustrated in simplified manner by active device portion 140 of semiconductor body 108 in FIG. 1).

A vertical distance vd between the first surface 106 and a top surface 116 of the contact pad structure 102 may be in a range from 2 μm to 50 μm. A width w of the dielectric spacer 1101 at a bottom side of the dielectric spacer 1101 may be larger than a thickness t1 of the first liner dielectric 1102 on the top surface 116 of the contact pad structure 102. The width w of the dielectric spacer 1101 at a bottom side of the dielectric spacer 1101 may be smaller than a thickness t2 of the second liner dielectric 1103 on the top surface 116 of the contact pad structure 102. The width w of the dielectric spacer 1101 at a bottom side of the dielectric spacer 1101 may be also be larger or equal to a thickness t2 of the second liner dielectric 1103 on the top surface 116 of the contact pad structure 102.

Another example of a semiconductor device 100 is illustrated in the schematic cross-sectional view of FIG. 2. The semiconductor device 100 illustrated in FIG. 2 is based on the semiconductor device 100 illustrated in FIG. 1, but differs in that the first dielectric liner 1102 and the dielectric spacer 1101 are formed from a common dielectric processing layer 1100 and/or have a same material composition. For example, during a spacer etch process applied to the dielectric processing layer 1100, etch-back of the dielectric processing layer 1100 for forming the spacer dielectric 1101 may not fully, but only partly, remove the dielectric processing layer 1100 in regions 1107 next to the dielectric spacer 1101.

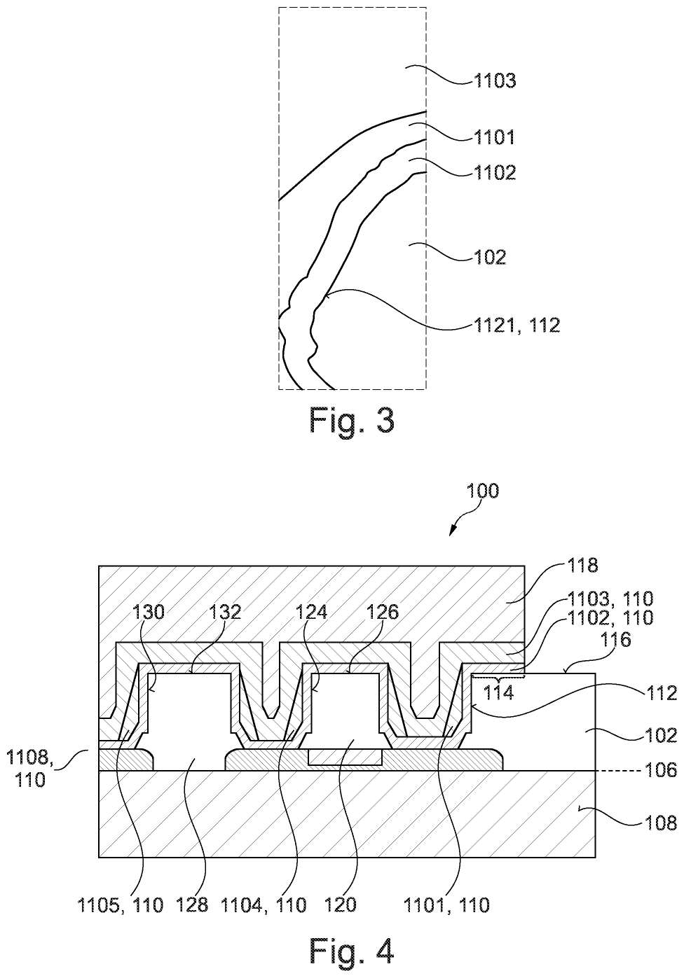

The cross-sectional view of FIG. 3 illustrates an image that is based on experimental analysis of a prepared semiconductor device sample by the focused ion beam (FIB) technique. Illustrated is a part 1121 of the sidewall 112 of the contact pad structure 102. The sidewall 112 of the contact pad structure 102 of the illustrated sample has a convex shape. Other examples may have a different shape of the sidewall, such as, for example, concave or non-tapered or tapered, but share the dielectric spacer 1101 at (e.g., directly adjoining to or close to) the sidewall 112 of the contact pad structure 102 for reducing or suppressing seamline generation.

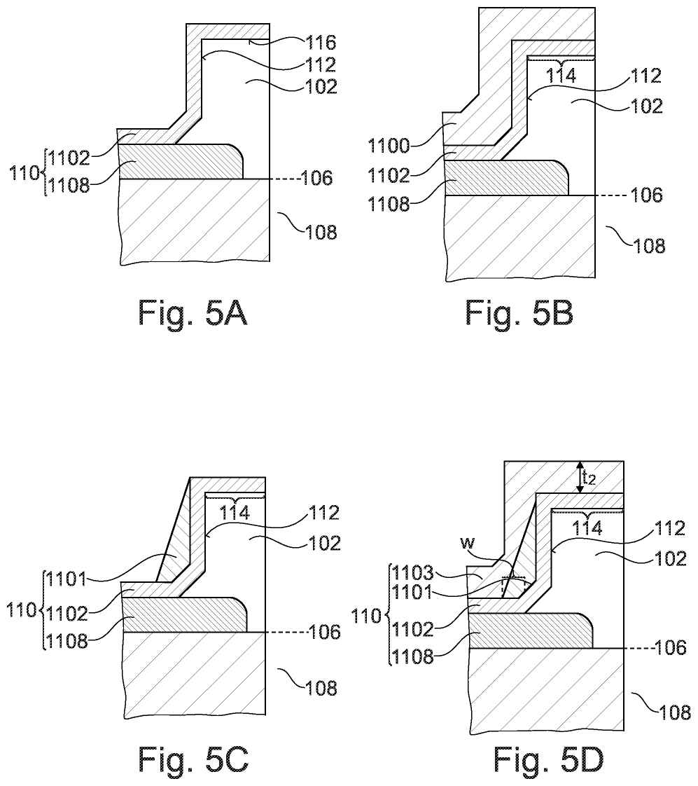

Another example of a semiconductor device 100 is illustrated in the schematic cross-sectional view of FIG. 4. The semiconductor device 100 illustrated in FIG. 4 is based on the semiconductor device 100 of FIG. 1, and further includes a gate runner line 120 electrically connecting gate electrodes of transistor cells to a gate contact pad structure. The gate runner line 120 is arranged between an edge of the semiconductor body 108 and the contact pad structure 102. The dielectric structure 110 extends between the contact pad structure 102 and the gate runner line 120 and lines a sidewall 124 and a top surface 126 of the gate runner line 120. The dielectric structure 110 further includes a second dielectric spacer 1104 at the sidewall 124 of the gate runner line 120. The semiconductor device 100 further includes a source or emitter runner line 128 electrically connecting source or emitter regions of transistor cells to the contact pad structure 102. The source or emitter runner line 128 is arranged between an edge of the semiconductor body 108 and the contact pad structure 102. The dielectric structure 110 extends between the contact pad structure 102 and the source or emitter runner line 128 and lines a sidewall 130 and a top surface 132 of the source or emitter runner line 128. The dielectric structure 110 includes a third dielectric spacer 1105 at the sidewall 130 of the source or emitter runner line 128.

The aspects and features mentioned and described together with one or more of the previously described examples and figures, may as well be combined with one or more of the other examples in order to replace a like feature of the other example or in order to additionally introduce the feature to the other example.

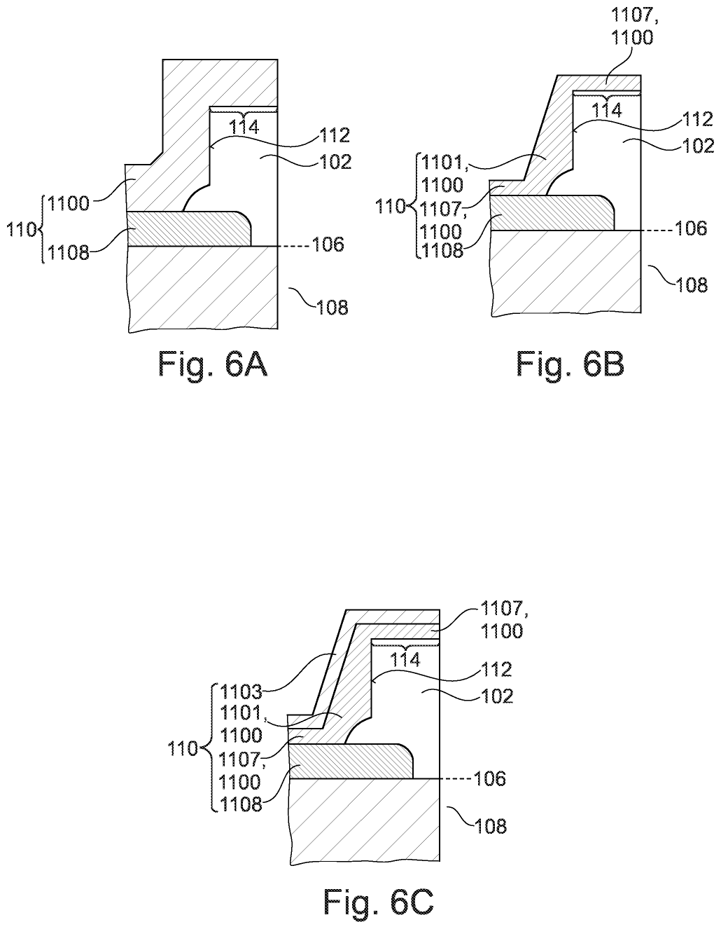

The schematic cross-sectional views of FIGS. 5A to 5D illustrate exemplary features of a method of producing a semiconductor device 100.

Referring to the schematic cross-sectional view of FIG. 5A, a dielectric part 1108 of a dielectric structure 110 is formed and directly adjoins to a first surface 106 of the semiconductor body 108. A contact pad structure 102 is formed over the first surface 106 of the semiconductor body 108. A first liner dielectric 1102 of the dielectric structure 110 is formed on the sidewall 112 and on the top surface 116 of the contact pad structure 102.

Referring to the schematic cross-sectional view of FIG. 5B, a spacer etch process is carried out by forming a dielectric processing layer 1100 on the first liner dielectric 1102. Referring to the schematic cross-sectional view of FIG. 5C, the dielectric processing layer 1100 is etched back so that a dielectric spacer 1101 remains at the sidewall 112 of contact pad structure 102. Referring to the schematic cross-sectional view of FIG. 5D, a second liner dielectric 1103 is formed on the dielectric spacer 1101 and on the first liner dielectric 1102.

The schematic cross-sectional views of FIGS. 6A to 6C illustrate further exemplary features of a method of producing a semiconductor device 100.

Referring to the schematic cross-sectional view of FIG. 6A, a dielectric part 1108 of a dielectric structure 110 is formed and directly adjoins to a first surface 106 of the semiconductor body 108. A contact pad structure 102 is formed over the first surface 106 of the semiconductor body 108. A spacer etch process is carried out by forming a dielectric processing layer 1100 on the dielectric part 1108 and on the contact pad structure 102. Referring to the schematic cross-sectional view of FIG. 6B, the dielectric processing layer 1100 is partly etched back so that the dielectric spacer 1101 and a part of the dielectric processing layer 1100 in regions 1107 next to the dielectric spacer 1101 remain over the first surface 106 of the semiconductor body 108. Referring to the schematic cross-sectional view of FIG. 6C, a second liner dielectric 1103 is formed on the dielectric spacer 1101 and on the first liner dielectric 1102. Referring to the schematic cross-sectional view of FIG. 6C, a second liner dielectric 1103 is formed on the remainder of the dielectric processing layer 1100.

Another example is based on the method illustrated in FIGS. 6A to 6C but further includes the process of forming the first dielectric liner 1102 as illustrated in FIG. 5B before forming the dielectric processing layer as illustrated in FIG. 6A.

Although specific embodiments have been illustrated and described herein, it will be appreciated by those of ordinary skill in the art that a variety of alternate and/or equivalent implementations may be substituted for the specific embodiments shown and described without departing from the scope of the disclosed subject matter. This application is intended to cover any adaptations or variations of the specific embodiments discussed herein. Therefore, it is intended that the disclosure be limited only by the claims and the equivalents thereof.

1. A semiconductor device, comprising:
a contact pad structure over a first surface of a semiconductor body; and
a dielectric structure lining:
a sidewall of the contact pad structure; and
a boundary area on a top surface of the contact pad structure, wherein the dielectric structure comprises a dielectric spacer at the sidewall of the contact pad structure.

2. The semiconductor device of claim 1, further comprising an interconnect on the top surface of the contact pad structure.

3. The semiconductor device of claim 1, wherein a part of the sidewall of the contact pad structure has a convex shape.

4. The semiconductor device of claim 1, wherein the contact pad structure comprises at least one of a source contact pad structure, an emitter contact pad structure, or a gate contact pad structure.

5. The semiconductor device of claim 1, wherein the dielectric spacer is arranged between a first liner dielectric of the dielectric structure and a second liner dielectric of the dielectric structure.

6. The semiconductor device of claim 5, wherein the first liner dielectric directly adjoins the sidewall of the contact pad structure, and the second liner dielectric directly adjoins the dielectric spacer.

7. The semiconductor device of claim 5, wherein the first liner dielectric comprises a SiN liner, and the second liner dielectric comprises a SiN liner and a silicate glass, wherein the silicate glass is arranged between the first liner dielectric and the SiN liner of the second liner dielectric.

8. The semiconductor device of claim 1, further comprising a polyimide resin on the second liner dielectric.

9. The semiconductor device of claim 1, further comprising at least one of:
a gate runner line electrically connecting gate electrodes of transistor cells to a gate contact pad structure, wherein the gate runner line is arranged between an edge of the semiconductor body and the contact pad structure, and the dielectric structure extends between the contact pad structure and the gate runner line and lines a sidewall and a top surface of the gate runner line; or
a gate finger line electrically connecting the gate electrodes of the transistor cells to the gate contact pad structure.

10. The semiconductor device of claim 9, wherein the dielectric structure comprises a second dielectric spacer at the sidewall of the gate runner line.

11. The semiconductor device of claim 1, further comprising a source or emitter runner line electrically connecting source or emitter regions of transistor cells to the contact pad structure, wherein the source or emitter runner line is arranged between an edge of the semiconductor body and the contact pad structure, and the dielectric structure extends between the contact pad structure and the source or emitter runner line and lines a sidewall and a top surface of the source or emitter runner line.

12. The semiconductor device of claim 11, wherein the dielectric structure comprises a third dielectric spacer at the sidewall of the source or emitter runner line.

13. The semiconductor device of claim 1, wherein the contact pad structure comprises at least one of Cu, Au, AlCu, Ag, or one or more alloys of at least two of Cu, Au, AlCu, or Ag.

14. The semiconductor device of claim 1, wherein a vertical distance between the first surface and a top surface of the contact pad structure is in a range from 2 μm to 50 μm.

15. The semiconductor device of claim 5, wherein a width of the dielectric spacer at a bottom side of the dielectric spacer is larger than a thickness of the first liner dielectric on the top surface of the contact pad structure.

16. The semiconductor device of claim 5, wherein a width of the dielectric spacer at a bottom side of the dielectric spacer is smaller than a thickness of the second liner dielectric on the top surface of the contact pad structure.

17. A method of producing a semiconductor device, comprising:
forming a contact pad structure over a first surface of a semiconductor body; and
forming a dielectric structure lining:
a sidewall of the contact pad structure; and
a boundary area on a top surface of the contact pad structure, wherein the dielectric structure comprises a dielectric spacer at the sidewall of the contact pad structure.

18. The method of claim 17, wherein forming the dielectric structure comprises:
forming a first liner dielectric of the dielectric structure on the sidewall of the contact pad structure and on the top surface of the contact pad structure;
forming the dielectric spacer by a spacer etch process; and
forming a second liner dielectric on the dielectric spacer and on the first liner dielectric.

19. The method of the claim 18, wherein forming the dielectric spacer by a spacer etch process comprises:
forming a dielectric processing layer over the first surface of the semiconductor body; and
partly etching back the dielectric processing layer so that:
a first part of the dielectric processing layer remains as the dielectric spacer; and
a second part of the dielectric processing layer remains over the first surface of the semiconductor body.

20. A method of producing a semiconductor device, comprising:
forming a contact pad structure over a first surface of a semiconductor body; and
forming a dielectric spacer, of a dielectric structure, by a spacer etch process, wherein the dielectric structure lines:
a sidewall of the contact pad structure; and
a boundary area on a top surface of the contact pad structure.
